(19) United States
(12) Patent Application Publication
(10) Pub. No.: US 2021/0339338 A1
(43) Pub. Date: Nov. 4, 2021

(54) LASER CUTTING METHOD FOR A WAFER

(71) Applicant: Powertech Technology Inc., Hukou Township (TW)

(72) Inventors: Chui-Liang CHIU, Hukou Township (TW); Kun-Chi HSU, Hukou Township (TW); Chin-Ta WU, Hukou Township (TW); Ching-Lin TSENG, Hukou Township (TW); Chia-Wei LIN, Hukou Township (TW); Jentung Tseng, Hukou Township (TW)

(73) Assignee: Powertech Technology Inc., Hukou Township (TW)

(21) Appl. No.: 16/997,223

(22) Filed: Aug. 19, 2020

(30) Foreign Application Priority Data
May 4, 2020 (TW) 109114827

(51) Int. Cl. B23K 26/042; H01L 21/784; B23K 26/364

(52) U.S. Cl. CPC B23K 26/042; B23K 2103/56; B23K 26/364; H01L 21/784

(57) ABSTRACT

A laser cutting method for a wafer is provided. First, an active side of a wafer is cut by a laser to form multiple cutting grooves so that the thicker and harder layer of the integrated circuit on the active side is cut. Then the stealth laser is used to cut the backside of the wafer by aligning the beams of the stealth laser with the cutting grooves. Therefore, the cutting grooves easily extend to the backside of the wafer and penetrate through the wafer to dice the wafer into multiple independent chips.

### CROSS-REFERENCE TO RELATED APPLICATIONS

This application is based upon and claims priority under 35 U.S.C. 119 from Taiwan Patent Application No. 109114827 filed on May 4, 2020, which is hereby specifically incorporated herein by this reference thereto.

### BACKGROUND OF THE INVENTION

### 1. Field of the Invention

The present invention relates to a cutting method for a wafer, and more particularly to a laser cutting method for a wafer.

### 2. Description of the Prior Arts

Semiconductor packages are produced from the packaging for the chips, which are cut off from a wafer by a necessary cutting process. Nowadays the conventional method for cutting a wafer are listed as below:

1. The wafer is directly cut by a blade saw. However, the chips cut by the blade saw may have the fracture and the disruption occurred to the front side, the backside and the lateral side to damage the active area of the chip.

2. The wafer is inducted with the process of laser grooving and cut by the blade saw, so that the issue of the fracture and the disruption occurred to the chip may be eliminated. However, the rigidity of the wafer for anti-bending maybe weakened.

3. The wafer is directly cut by a stealth dicing. Although the rigidity of the wafer for anti-bending may be maintained, the relatively thicker metal layer of the integrated circuit on the active side of the wafer may not be comprehensively cut off.

As a result, either the blade saw or laser cutting for the wafer has the drawbacks for the chips. Thus, a modification for the cutting method for a wafer is demanded to guarantee the quality of the chips.

To overcome the shortcomings, the present invention provides a laser cutting method for a wafer to mitigate or to obviate the aforementioned problems.

### SUMMARY OF THE INVENTION

A major objective of the present invention is to provide a novel laser cutting method for a wafer to decrease the condition of the fracture and the disruption happened to the chip.

To achieve the above objective, a laser cutting method for a wafer, comprising:

(a) performing a laser cutting on an active side of a wafer to form multiple cutting grooves; and

(b) performing a stealth laser cutting on a backside of the wafer by aligning the cutting grooves to extend each of the cutting grooves to the backside so that the cutting grooves penetrate through the wafer to dice the wafer into multiple independent chips.

From the above description, the present invention primarily provides a laser for cutting a half portion of the active side of the wafer so that the integrated circuits on the active side is cut in advance. Then the backside of the wafer is cut by the beams of the stealth laser. Therefore, the cutting grooves on the active side extend towards the backside of the wafer and the wafer is diced into multiple independent chips at the mean time. Because the integrated circuits includes metal layer, different silicon lattice layer and the insulating layer, the steps that using the laser to cut off those layers in advance and then performing the stealth laser cutting the silicon base layer of the wafer makes it easier for the cutting grooves to penetrate through the wafer to dice the wafer into multiple independent chips. Therefore, the difficulties that stealth laser is incapable of cutting the thicker and harder layer (such as the metal layer) of the integrated circuit on the active side is resolved.

Other objectives, advantages and novel features of the invention will become more apparent from the following detailed description when taken in conjunction with the accompanying drawings.

### BRIEF DESCRIPTION OF THE DRAWINGS

FIGS. 1A to 1N are schematic cross sectional views of different steps of a laser cutting method for a wafer of the present invention; and

FIGS. 2A to 2D are perspective views of different steps of another laser cutting method for a wafer of the present invention.

### DETAILED DESCRIPTION OF THE EMBODIMENTS

The present invention relates to a laser cutting method for a wafer, multiple embodiments are illustrated with the figures below to describe the laser cutting method for a wafer in accordance with the invention in detail.

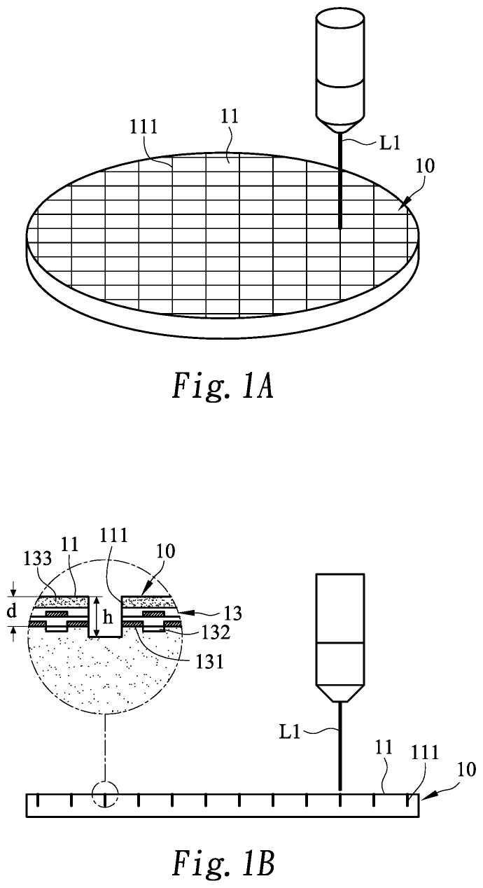

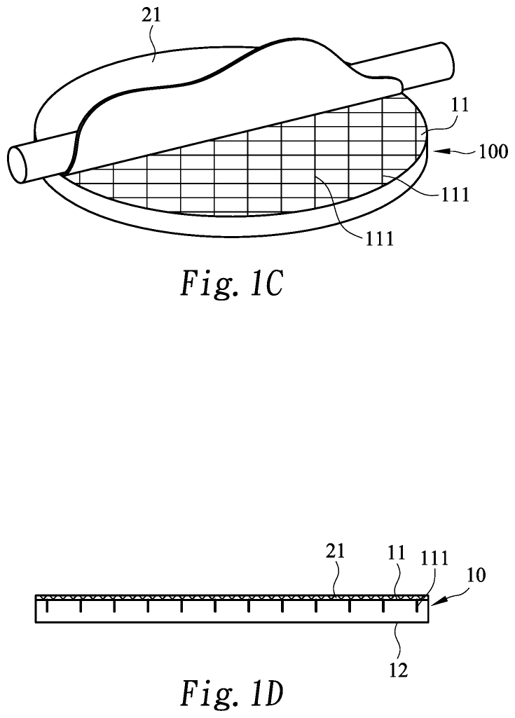

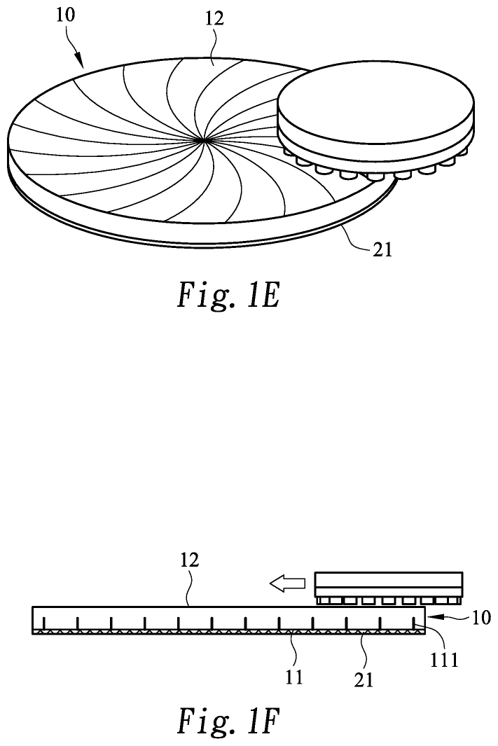

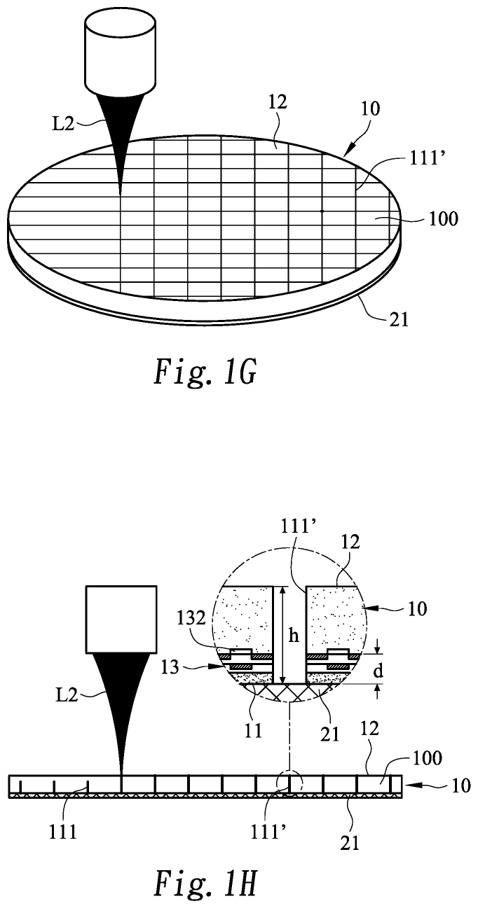

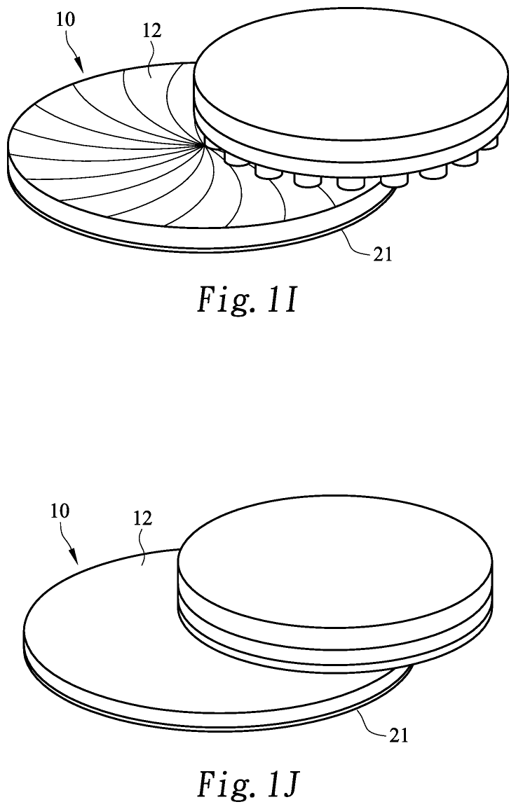

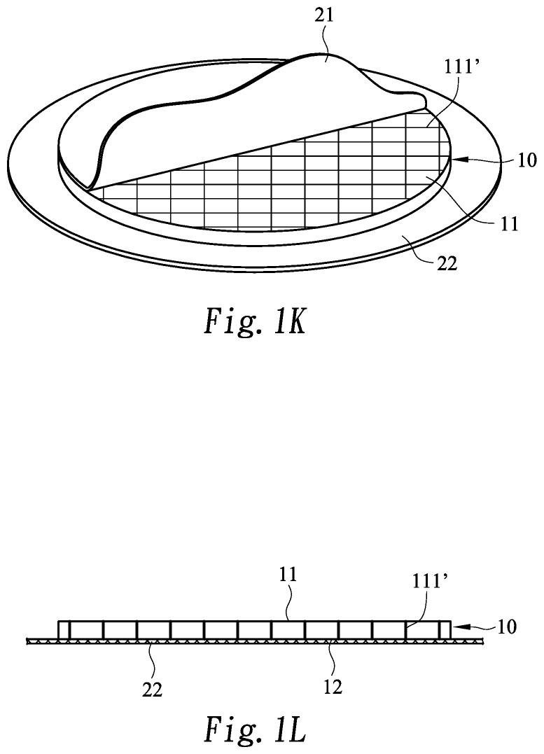

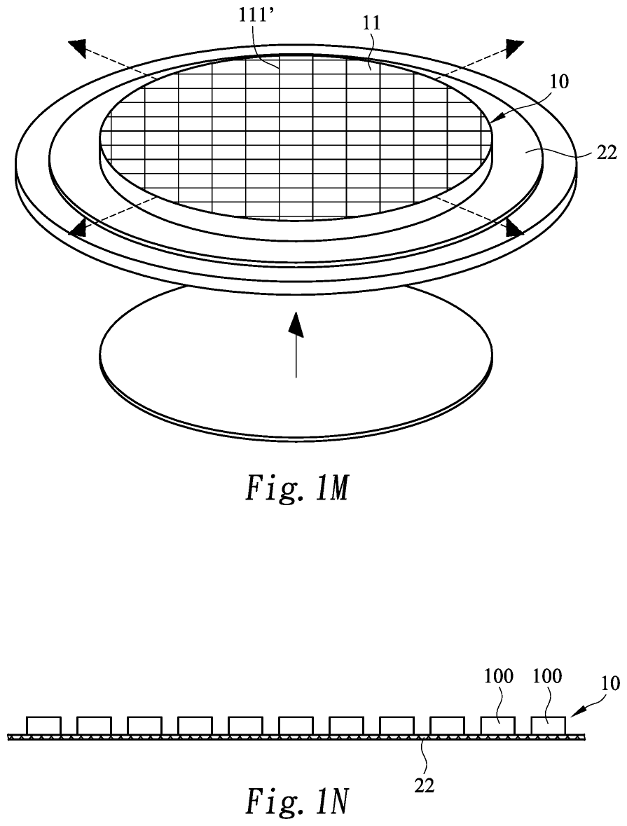

With reference to FIGS. 1A to 1N, a first embodiment of a laser cutting method for a wafer in accordance with the present invention comprising the following steps (a) to (c):

In the step (a), as shown in FIG. 1A and FIG. 1B, a wafer 10 is provided. The wafer 10 has an active side 11, which is placed upward. A laser L1 is provided for cutting the active side 11 of the wafer 10 to form multiple cutting grooves 111 interlacing with each other on the active side 11. The active side 11 of the wafer 10 has an integrated circuit 13. The integrated circuit 13 includes a metal layer 131, different silicon lattice layers 132 and an insulating layer (such as Polyimide). In one embodiment as shown in FIG. 1B, the depth h of each of the cutting grooves is more than a distance d from the active side 11 of the wafer 10 to the metal layer 131 of the integrated circuit 13 at a minimum. In this embodiment, the laser L1 used in step (a) is a short pulse laser.

In the step (b), as shown in FIG. 1C and FIG. 1D, a first tape 21 is provided. The active side 11 of the wafer 10 is attached to the first tape 21, then the wafer 10 is inverted to make a backside 12 of the wafer 10 to flip upward. In one embodiment as shown in FIG. 1E and FIG. 1F, the backside 12 of the wafer 10 is performed with a first grinding process so that the wafer 10 becomes thinner. With further reference to FIG. 1G and FIG. 1H, a stealth laser L2 is provided. The stealth laser L2 is used to cut the backside 12 of the wafer 10 after the implementation of the grinding process. As shown in FIGS. 1A and 1G, the beams of the stealth laser L2 from the backside 12 of the wafer 10 respectively align with the cutting grooves 111 on the active side 11. Therefore, each of the cutting grooves 111 extends towards the backside 12 of the wafer 10 and penetrates through the wafer 10 to dice the wafer 10 into multiple independent chips 100. In this embodiment, a wave length of the stealth laser L2 used in the step (b) is longer than the wave length of the short pulse laser L1 used in step (a). Additionally, as shown in FIG. 1I, the backside 12 of the wafer 10 is further performed with a second grinding process so that the wafer 10 would have a predetermined thickness. Afterwards, the backside 12 of the wafer 10 is polished as shown in FIG. 1J.

In the step (c) as shown in FIG. 1K, a second tape 22 is provided for the inverted wafer 10. The second tape 22 is attached to the backside 12 of the wafer 10 and the first tape 21 is removed from the active side 11 as shown in FIG. 1L. With further reference to FIG. 1M, expanded the second tape 22 (i.e. a rear side of the second tape 22 as shown in FIG. 1L) so that the intervals between the chips 100 attached to the second tape 22 are enlarged as shown in FIG. 1N. Then the chips 100 are divided to each other.

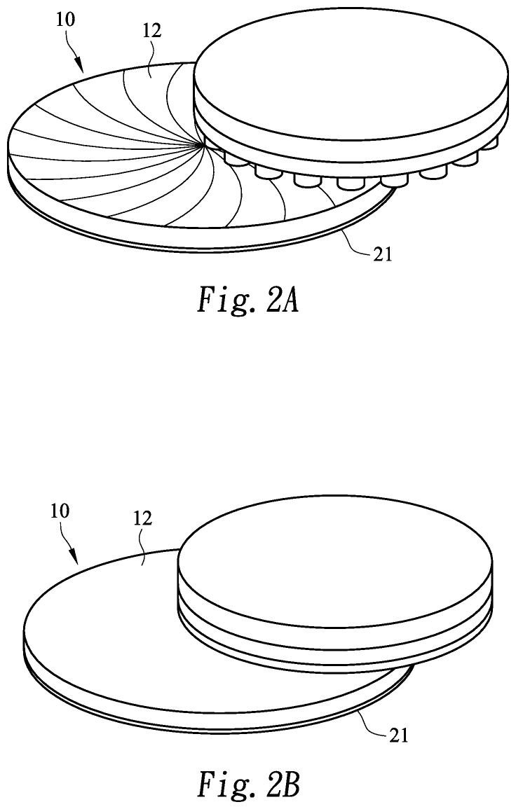

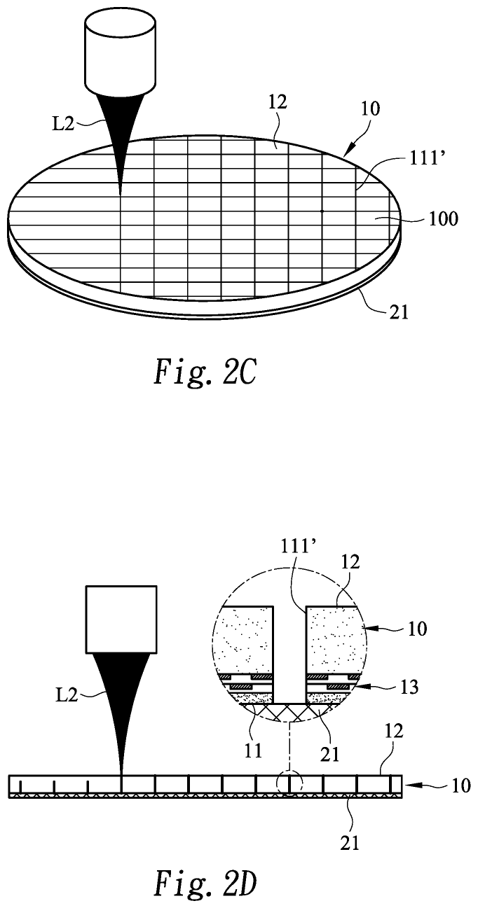

With further reference to FIG. 2A to FIG. 2D, a second embodiment of a laser cutting method for a wafer in accordance with the present invention is provided. In the second embodiment, the step (a) to step (c) are the similar to the steps performed in the first embodiment. The step (a) of the second embodiment performs the same process as the first embodiment shown in FIG. 1A and FIG. 1B. The step (c) of the second embodiment performs the same process as the first embodiment shown from FIG. 1K to FIG. 1N. Thus, for the steps (a) and (c) of the second embodiment, the detailed descriptions are omitted for purposes of brevity.

In the step (b) of the second embodiment, with reference to FIG. 1C and FIG. 1D, an active side 11 of the wafer 10 is attached to a first tape 21, then the wafer 10 is inverted to make a backside 12 of the wafer 10 to flip upward as shown in FIG. 2A and FIG. 2B. In this embodiment, the backside 12 of the wafer 10 is performed with a grinding and a polishing process so that the wafer 10 would have a predetermined thickness at once. With further reference to FIG. 2C and FIG. 2D, a stealth laser L2 is provided. The stealth laser L2 is used to cut the backside 12 of the wafer 10 after the implementation of the grinding process. As shown in FIG. 1A, each of the cutting grooves 111 formed on the active side 11 is aligned by the beam of the stealth laser L2 from the backside 12 of the wafer 10. Therefore, each of the cutting grooves 111 extends towards the backside 12 of the wafer 10. As shown in the figures, the cutting grooves 111′ that penetrates through the wafer 10 are formed and the wafer 10 is diced into multiple independent chips 100. In this embodiment, a wave length of the stealth laser L2 used in step (b) is longer than the wave length of the short pulse laser L1 used in step (a).

In conclusion, the laser cutting method for a wafer in accordance with the present invention primarily provides a laser for cutting a half portion of the active side of the wafer preliminarily so that the integrated circuits on the active side is cut in advance. Next cutting the backside of the wafer by the beams of the stealth laser. Therefore, the cutting grooves on the active side extend towards the backside of the wafer and the wafer is diced into multiple independent chips at the mean time. Because the integrated circuits includes metal layer, different silicon lattice layer and the insulating layer, the steps that using the laser to cut off those layers in advance and then performing the stealth laser to cut the silicon base layer of the wafer afterward makes it easier for the cutting grooves to penetrate through the wafer to dice the wafer into multiple independent chips. Therefore, the problem that the stealth laser is incapable of cutting the thicker and harder layer (such as the metal layer) of the integrated circuit on the active side is resolved.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A laser cutting method for a wafer, comprising steps of:
(a) performing a laser cutting on an active side of a wafer to form multiple cutting grooves; and
(b) performing a stealth laser cutting on a backside of the wafer by aligning beams of the stealth laser with the cutting grooves to extend each of the cutting grooves to the backside so that the cutting detents grooves penetrate through the wafer to dice the wafer into multiple independent chips, which forms multiple intervals between the chips.

2. The laser cutting method for a wafer as claimed in claim 1, wherein in the step (a), the active side of the chip has an integrated circuit with multiple metal layers.

3. The laser cutting method for a wafer as claimed in claim 2, wherein in the step (a), the depth of each of the cutting grooves is more than a distance from the active side of the wafer to the metal layer nearest the backside of the wafer.

4. The laser cutting method for a wafer as claimed in claim 3, wherein the step (b) comprises steps of:
(b1) attaching the active side of the wafer to a first tape and inverting the wafer;
(b2) performing a stealth laser cutting on a backside of the wafer by aligning beams of the stealth laser with the cutting grooves.

5. The laser cutting method for a wafer as claimed in claim 4, wherein the step (b1) further comprises a step of performing a first grinding process to the backside of the wafer to make the wafer thinner.

6. The laser cutting method for a wafer as claimed in claim 5, wherein after the step (b2), the method further comprises a step of:
(b3) performing a second grinding and polishing process to the backside of the wafer after the step (b2).

7. The laser cutting method for a wafer as claimed in claim 4, wherein in the step (b1) further comprising performing a grinding and polishing process to the backside of the wafer to make the wafer thinner.

8. The laser cutting method for a wafer as claimed in claim 4 wherein after the step (b2), the method further comprises a step of:
(c) performing a die expanding process to the wafer to expand the intervals between the chips.

9. The laser cutting method for a wafer as claimed in claim 5 wherein after the step (b2), the method further comprises a step of:
(c) performing a die expanding process to the wafer to expand the intervals between the chips.

10. The laser cutting method for a wafer as claimed in claim 6 wherein after the step (b3), the method further comprises a step of:
(c) performing a die expanding process to the wafer to expand the intervals between the chips.

11. The laser cutting method for a wafer as claimed in claim 7 wherein after the step (b2), the method further comprises a step of:
(c) performing a die expanding process to the wafer to expand the intervals between the chips.

12. The laser cutting method for a wafer as claimed in claim 8, wherein in the step (c) further comprises steps of:
(c1) inverting the wafer and attaching the backside of the wafer to a second tape as well as removing the first tape; and
(c2) elevating a surface of the second tape, which is not attached to the backside of the wafer, to expand the intervals between the chips.

13. The laser cutting method for a wafer as claimed in claim 9, wherein in the step (c) further comprises steps of:
(c1) inverting the wafer and attaching the backside of the wafer to a second tape as well as removing the first tape; and
(c2) elevating a surface of the second tape, which is not attached to the backside of the wafer, to expand the intervals between the chips.

14. The laser cutting method for a wafer as claimed in claim 10, wherein in the step (c) further comprises steps of:
(c1) inverting the wafer and attaching the backside of the wafer to a second tape as well as removing the first tape; and
(c2) elevating a surface of the second tape, which is not attached to the backside of the wafer, to expand the intervals between the chips.

15. The laser cutting method for a wafer as claimed in claim 11, wherein in the step (c) further comprises steps of:
(c1) inverting the wafer and attaching the backside of the wafer to a second tape as well as removing the first tape; and
(c2) elevating a surface of the second tape, which is not attached to the backside of the wafer, to expand the intervals between the chips.

16. The laser cutting method for a wafer as claimed in claim 1, wherein the laser used in the step (a) is a short pulse laser having a wave length shorter than a wave length of the stealth laser used in the step (b).
